(19) United States
(12) Patent Application Publication
(10) Pub. No.: US 2025/0286030 A1
(43) Pub. Date: Sep. 11, 2025

(54) SEMICONDUCTOR PACKAGE

(71) Applicant: Samsung Electronics Co., Ltd., Suwon-si (KR)

(72) Inventors: SANG SUB SONG, Suwon-si (KR); HEEYOUB KANG, Suwon-si (KR); KEUNG BEUM KIM, Suwon-si (KR); TONGSUK KIM, Suwon-si (KR)

(21) Appl. No.: 18/985,137

(22) Filed: Dec. 18, 2024

(30) Foreign Application Priority Data
Mar. 8, 2024 (KR) 10-2024-0033370

(51) Int. Cl. H01L 25/16; H01L 23/00; H01L 23/31; H01L 23/367; H01L 23/498; H01L 23/538; H01L 23/64; H10B 80/00; H10D 80/30

(52) U.S. Cl. CPC H01L 25/16; H01L 23/3128; H01L 23/3677; H01L 23/49838; H01L 23/5385; H01L 23/5386; H01L 23/642; H10B 80/00; H10D 80/30; H01L 24/16; H01L 24/48; H01L 2224/16225; H01L 2224/16227; H01L 2224/16238; H01L 2224/48225; H01L 2924/1431; H01L 2924/19041

(57) ABSTRACT

Disclosed is a semiconductor package comprising a first redistribution substrate, first and second semiconductor chips mounted on a top surface of the first redistribution substrate and horizontally spaced apart, a molding layer disposed on the top surface of the first redistribution substrate and surrounding the first and second semiconductor chips, a second redistribution substrate disposed on a top surface if the molding layer, an upper package mounted on a top surface of the second redistribution substrate, a vertical electrical connection structure disposed on one side of the first and second semiconductor chips and connecting the first redistribution substrate to the second redistribution substrate, a plurality of external connection terminals disposed on a bottom surface of the first redistribution substrate, and a bridge chip and a capacitor chip that are mounted on the bottom surface of the first redistribution substrate.

### CROSS-REFERENCE TO RELATED APPLICATION

This U.S. nonprovisional application claims priority under 35 U.S.C § 119 to Korean Patent Application No. 10-2024-0033370 filed on Mar. 8, 2024 in the Korean Intellectual Property Office, the disclosure of which is hereby incorporated by reference in its entirety.

### BACKGROUND

The present inventive concepts relate to a semiconductor package and a method of fabricating the same, and more particularly, to a semiconductor package including a bridge chip and a method of fabricating the same.

With the continual development of the electronics industry, electronic products have ever-increasing demands for high performance, high speed, and compact size. One approach that has developed as part of efforts to meet these ever-increasing demands is a packaging technology in which a plurality of semiconductor chips are mounted in a single package.

A semiconductor package is provided to implement an integrated circuit chip for use in electronic products. Commonly, a semiconductor package is configured such that a semiconductor chip is mounted on a printed circuit board (PCB) and bonding wires or bumps are used to electrically connect the semiconductor chip to the printed circuit board. Compact size, small weight, and/or low manufacturing cost are typical goals of semiconductor package design. As technologies have evolved, the use of semiconductor packages has expanded into new applications, such as high-capacity mass storage devices.

As the extent of integration of semiconductor chips has increased, their size has decreased, making it increasingly difficult to form and test the electrical connections between pads on the chips and external connection pads of semiconductor packages containing the chips. Additionally, the reductions in semiconductor chip size can present challenges with respect to acquiring diversified mount boards in accordance with the size of the semiconductor chip. A fan-out panel level package is one approach to addressing the problems described above. However, in the case of a fan-out panel semiconductor package, the area of redistribution lines is inevitably greater than that of the semiconductor chip. Accordingly, there is a problem in that an excessively large area is given to the semiconductor chip compared to the utilization of the semiconductor chip.

### SUMMARY

Some embodiments of the present inventive concepts provide a compact-sized semiconductor package.

Some embodiments of the present inventive concepts provide a semiconductor package with improved electrical properties and improved thermal radiation.

The object of the present inventive concepts is not limited to the mentioned above, and other objects which have not been mentioned above will be clearly understood to those skilled in the art from the following description.

According to some embodiments of the present inventive concepts, a semiconductor package may comprise a first redistribution substrate, a first semiconductor chip and a second semiconductor chip that are mounted on a top surface of the first redistribution substrate and horizontally spaced apart from each other, a molding layer disposed on the top surface of the first redistribution substrate and surrounding the first semiconductor chip and the second semiconductor chip, a second redistribution substrate disposed on a top surface of the molding layer, an upper package mounted on a top surface of the second redistribution substrate, a vertical electrical connection structure disposed on one side of the first and second semiconductor chips and connecting the first redistribution substrate to the second redistribution substrate, a plurality of external connection terminals disposed on a bottom surface of the first redistribution substrate, and a bridge chip and a capacitor chip that are mounted on the bottom surface of the first redistribution substrate and are disposed between a first set of the external connection terminals and a second set of the external connection terminals.

According to some embodiments of the present inventive concepts, a semiconductor package may comprise a lower package and an upper package mounted on the lower package. The lower package may include a first redistribution substrate, a first logic chip and a second logic chip that are mounted on a top surface of the first redistribution substrate in a first region of the semiconductor package, a molding layer disposed on the top surface of the first redistribution substrate and surrounding the first logic chip and the second logic chip, a vertical electrical connection structure disposed on the top surface of the first redistribution substrate in a second region of the semiconductor package, the second region horizontally spaced apart from the first region, and a bridge chip mounted on a bottom surface of the first redistribution substrate. The upper package may include an upper package substrate, a memory chip mounted on a top surface of the upper package substrate, and an upper molding layer disposed on the top surface of the upper package substrate and covering a top surface of the memory chip. The upper package may be disposed in the second region of the semiconductor package.

According to some embodiments of the present inventive concepts, a semiconductor package may comprise a first redistribution substrate, a first semiconductor chip and a second semiconductor chip that are mounted on a top surface of the first redistribution substrate in a first region of the semiconductor package, a second redistribution substrate disposed above the first semiconductor chip and the second semiconductor chip, a vertical electrical connection structure disposed on the top surface of the first redistribution substrate in a second region of the semiconductor package and connecting the first redistribution substrate to the second redistribution substrate, the second region horizontally spaced apart from the first region an upper package mounted on a top surface of the second redistribution substrate in the second region, a thermal radiation member attached to the top surface of the second redistribution substrate in the first region, a plurality of external connection terminals disposed on a bottom surface of the first redistribution substrate, and a bridge chip that is mounted on the bottom surface of the first redistribution substrate in the first region and is disposed between a first set of the external connection terminals and a second set of the external connection terminals.

### BRIEF DESCRIPTION OF DRAWINGS

FIGS. 1 to 14 illustrate cross-sectional views showing a semiconductor package according to some embodiments of the present inventive concepts.

### DETAILED DESCRIPTION OF EMBODIMENTS

Throughout the specification, when a component is described as “including” a particular element or group of elements, it is to be understood that either the component is formed of only the element or the group of elements, or the element or group of elements may be combined with additional elements to form the component, unless the context indicates otherwise. The term “consisting of,” on the other hand, indicates that a component is formed only of the element(s) listed.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

The present disclosure now will be described more fully hereinafter with reference to the accompanying drawings, in which various embodiments are shown. The invention may, however, be embodied in many different forms and should not be construed as limited to the example embodiments set forth herein. These example embodiments are just that—examples—and many implementations and variations are possible that do not require the details provided herein. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention.

The following will now describe a semiconductor package according to the present inventive concepts with reference to the accompanying drawings.

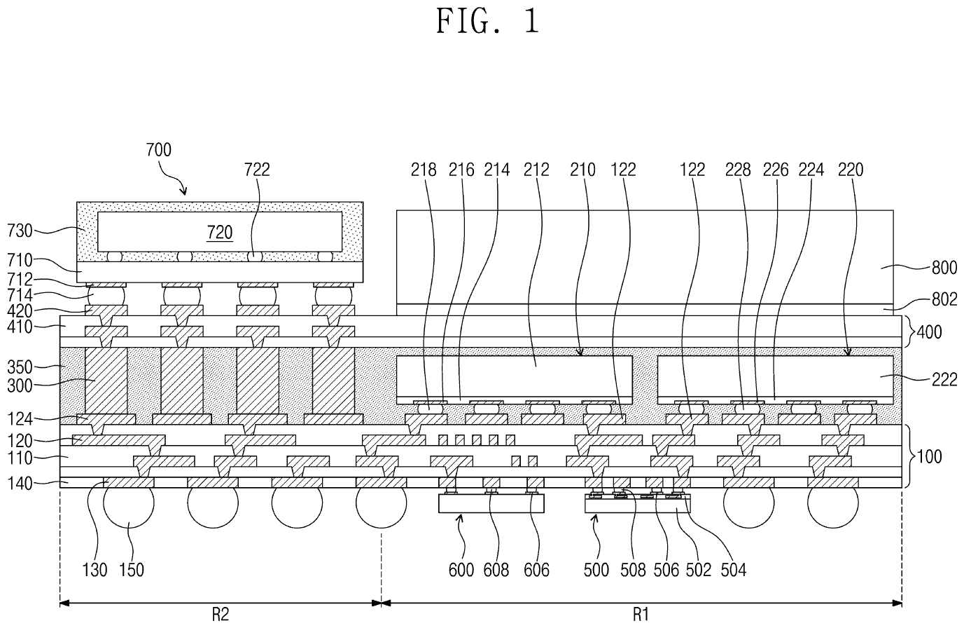

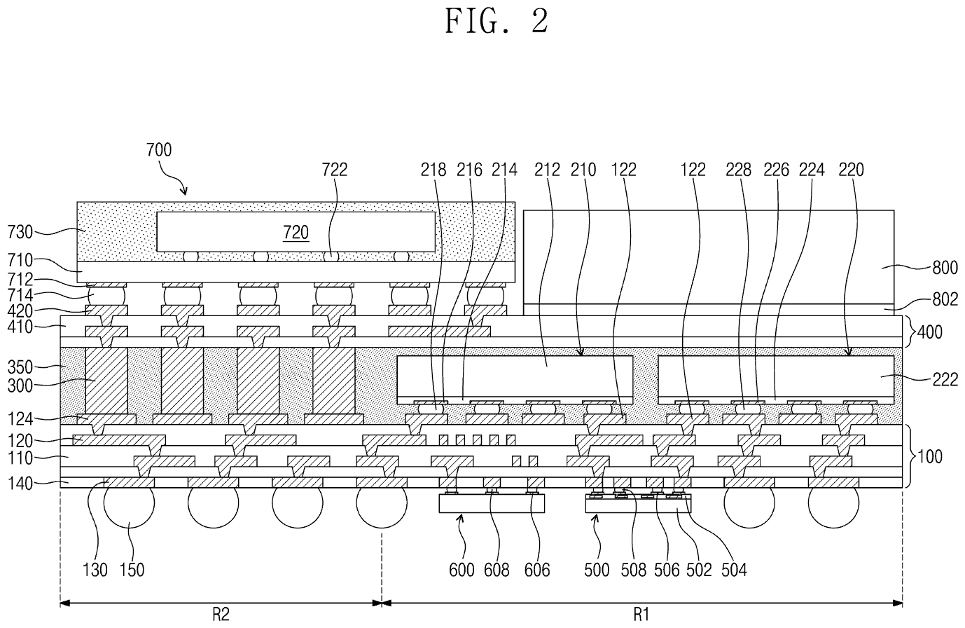

FIGS. 1 and 2 illustrate cross-sectional views showing a semiconductor package according to some embodiments of the present inventive concepts.

Referring to FIG. 1, a lower package may be provided. The lower package may include a first redistribution substrate 100, a first semiconductor chip 210, a second semiconductor chip 220, conductive posts 300, a molding layer 350, a second redistribution substrate 400, a bridge chip 500, and a passive device chip 600.

The first redistribution substrate 100 may include one or more first substrate wiring layers that are stacked on each other. Each of the first substrate wiring layers may include a first substrate dielectric pattern 110 and a first substrate wiring pattern 120 in the first substrate dielectric pattern 110. The first substrate wiring pattern 120 of one first substrate wiring layer may be electrically connected to the first substrate wiring pattern 120 of an adjacent other first substrate wiring layer. As used herein, components described as being “electrically connected” are configured such that an electrical signal can be transferred from one component to the other (although such electrical signal may be attenuated in strength as it is transferred and may be selectively transferred).

Any particular first substrate dielectric pattern 110 may include a dielectric polymer or a photo-imageable dielectric (PID). For example, the photo-imageable dielectric may include at least one selected from photosensitive polyimide, polybenzoxazole (PBO), phenolic polymers, and benzocyclobutene polymers. Alternatively, the first substrate dielectric pattern 110 may include a dielectric material. For example, the first substrate dielectric pattern 110 may include silicon oxide (SiO), silicon nitride (SiN), silicon oxynitride (SiON), or dielectric polymers.

Any particular first substrate wiring pattern 120 may be provided on a first substrate dielectric pattern 110. The first substrate wiring pattern 120 may horizontally extend on the first substrate dielectric pattern 110. The first substrate wiring pattern 120 may be provided on a top surface of the first substrate dielectric pattern 110. The first substrate wiring pattern 120 may protrude onto the top surface of the first substrate dielectric pattern 110. On the first substrate dielectric pattern 110, the first substrate wiring pattern 120 may be covered with another first substrate dielectric pattern 110 disposed thereon. The first substrate wiring pattern 120 provided on an uppermost first substrate wiring layer may serve as substrate pads to which are coupled the first semiconductor chip 210, the second semiconductor chip 220, and the conductive posts 300 which will be discussed below. For example, a portion of the first substrate wiring pattern 120 provided on the uppermost first substrate wiring layer may be first substrate pads 122 on which the first and second semiconductor chips 210 and 220 are mounted as discussed below, and another portion of the first substrate wiring pattern 120 provided on the uppermost first substrate wiring layer may be second substrate pads 124 on which the conductive posts 300 are coupled. As discussed above, the first substrate wiring pattern 120 may be a pad or line part of the first substrate wiring layer. For example, the first substrate wiring pattern 120 may be a component for horizontal redistribution in the first redistribution substrate 100. The first substrate wiring pattern 120 may include a conductive material. For example, the first substrate wiring pattern 120 may include metal, such as copper (Cu).

The first substrate wiring pattern 120 may have a damascene structure. For example, the first substrate wiring pattern 120 may have a via that protrudes from a bottom surface thereof. The via may be a component for vertically connecting the first substrate wiring patterns 120 of neighboring first substrate wiring layers. Alternatively, the via may be a component for connecting the first substrate wiring pattern 120 of a lowermost first substrate wiring layer to external pads 130 which will be discussed below. For example, the via may extend from the bottom surface of the first substrate wiring pattern 120 to penetrate the first substrate dielectric pattern 110, thereby being coupled to a top surface of the first substrate wiring pattern 120 of an underlying first substrate wiring layer. For another example, the via may extend from the bottom surface of the first substrate wiring pattern 120 to penetrate a lowermost first substrate dielectric pattern 110, thereby being coupled to top surfaces of the external pads 130. In this configuration, an upper portion of the first substrate wiring pattern 120 positioned on the first substrate dielectric pattern 110 may be a head part used as a horizontal line or pad, and the via of the first substrate wiring pattern 120 may be a tail part. The tail part may have a width less than that of the head part. The width of the tail part may decrease with increasing distance from the head part of the first substrate wiring pattern 120. For example, the tail part may have a tapered shape. The first substrate wiring pattern 120 may have a T shape.

The external pads 130 may be provided on a bottom surface of the lowermost first substrate wiring layer. The external pads 130 may be electrically connected to the first substrate wiring pattern 120. The external pads 130 may serve as pads to which external terminals 150 are coupled.

A substrate protection layer 140 may be provided. The substrate protection layer 140 may cover the bottom surface of the lowermost first substrate wiring layer and expose the external pads 130. The external terminals 150 may be provided on exposed bottom surfaces of the external pads 130. The external terminals 150 may include solder balls or solder bumps, and based on type and arrangement of the external terminals 150, a semiconductor package may be provided in the form of one of a ball grid array (BGA) type, a fine ball-grid array (FBGA) type, and a land grid array (LGA) type.

The first redistribution substrate 100 may be provided as discussed above. The present inventive concepts, however, are not limited thereto. The first redistribution substrate 100 may be a printed circuit board (PCB). For example, the first redistribution substrate 100 may have a core layer and peripheral parts for interconnection on top and bottom of the core layer.

The first and second semiconductor chips 210 and 220 are mounted on a top surface of the first redistribution substrate 100 in a first region R1 of the semiconductor package. The conductive posts 300 are provided on the top surface of the first redistribution substrate 100 in a second region R2 of the semiconductor package. The second region R2 may be positioned on one side of the first region R1. The first region R1 and the second region R2 may be disposed horizontally spaced apart from each other.

The first semiconductor chip 210 and the second semiconductor chip 220 may be provided on the top surface of the first redistribution substrate 100. The first semiconductor chip 210 and the second semiconductor chip 220 may be disposed on the top surface of the first redistribution substrate 100 in the first region R1.

The first semiconductor chip 210 may include a first chip base layer 212 and a first chip wiring layer 214.

The first chip base layer 212 may include or may be a semiconductor substrate, such as a semiconductor wafer. The first chip base layer 212 may be a silicon (Si) substrate, a silicon-on-insulator (SOI) substrate, a germanium (Ge) substrate, a germanium-on-insulator (GOI) substrate, a silicon-germanium (SiGe) substrate, a III-V group semiconductor substrate, or an epitaxial film substrate obtained by performing selective epitaxial growth (SEG). The first chip base layer 212 may include, for example, at least one selected from silicon (Si), germanium (Ge), silicon germanium (SiGe), gallium arsenic (GaAs), indium gallium arsenic (InGaAs), aluminum gallium arsenic (AlGaAs), and a mixture thereof. A first integrated circuit may be provided on a bottom surface of the first chip base layer 212. The first integrated circuit may include a logic circuit. For example, the first semiconductor chip 210 may be a logic chip that includes the first integrated circuit, and the first integrated circuit may include a logic circuit. In some examples, the first semiconductor chip 210 may include a logic chip including a memory element, a logic semiconductor chip including various integrated elements, or a passive device chip. A bottom surface of the first semiconductor chip 210 may be an active surface, and a top surface of the first semiconductor chip 210 may be an inactive surface. For example, the first semiconductor chip 210 may be disposed face-down on the first redistribution substrate 100.

The first chip wiring layer 214 may be disposed on the bottom surface of the first chip base layer 212. For example, the first chip wiring layer 214 may include a first chip dielectric pattern and a first chip wiring pattern that are formed on the bottom surface of the first chip base layer 212.

On the bottom surface of the first chip base layer 212, the first chip dielectric pattern may cover the first integrated circuit. The first chip dielectric pattern may include a dielectric material. For example, the first chip dielectric pattern may include silicon oxide (SiO), silicon nitride (SiN), silicon oxynitride (SiON), silicon carbonitride (SiCN), or a dielectric polymer. Alternatively, the first chip dielectric pattern may include a dielectric polymer or a photo-imageable dielectric (PID). For example, the photo-imageable dielectric may include at least one selected from photosensitive polyimide, polybenzoxazole, phenolic polymers, and benzocyclobutene polymers.

The first chip wiring pattern may be provided in the first chip dielectric pattern. The first chip wiring pattern may be electrically connected to the first integrated circuit on the bottom surface of the first chip base layer 212. The first chip wiring pattern may include a conductive material. For example, the first chip wiring pattern may include copper (Cu) or aluminum (Al).

The first semiconductor chip 210 may include first chip pads 216 provided on the bottom surface of the first semiconductor chip 210. The first chip pads 216 may be disposed on the bottom surface of the first chip wiring layer 214. The first chip pads 216 may be electrically connected through the first chip wiring pattern in the first chip wiring layer 214 to the first integrated circuit on the bottom surface of the first chip base layer 212.

In some examples, the first chip wiring layer 214 may further include a circuit pattern or a protection layer.

The first semiconductor chip 210 may be mounted on the top surface of the first redistribution substrate 100. For example, the first semiconductor chip 210 may be flip-chip mounted on the top surface of the first redistribution substrate 100. In this configuration, the first semiconductor chip 210 may be electrically connected through first connection terminals 218 to a set of the first substrate pads 122 of the first redistribution substrate 100. The first connection terminals 218 may be provided between the first chip pads 216 of the first semiconductor chip 210 and the set of the first substrate pads 122 of the first redistribution substrate 100.

The second semiconductor chip 220 may also be mounted on the top surface of the first redistribution substrate 100, and may be disposed horizontally spaced apart from the first semiconductor chip 210. The second semiconductor chip 220 may include a second chip base layer 222 and a second chip wiring layer 224.

The second chip base layer 222 may include or may be a semiconductor substrate, such as a semiconductor wafer. The second chip base layer 222 may be a silicon (Si) substrate, a silicon-on-insulator (SOI) substrate, a germanium (Ge) substrate, a germanium-on-insulator (GOI) substrate, a silicon-germanium (SiGe) substrate, a III-V group semiconductor substrate, or an epitaxial film substrate obtained by performing selective epitaxial growth (SEG). The second chip base layer 222 may include, for example, at least one selected from silicon (Si), germanium (Ge), silicon germanium (SiGe), gallium arsenic (GaAs), indium gallium arsenic (InGaAs), aluminum gallium arsenic (AlGaAs), and a mixture thereof. A second integrated circuit may be provided on a bottom surface of the second chip base layer 222. The second integrated circuit may include a logic circuit. For example, the second semiconductor chip 220 may be a logic chip that includes the second integrated circuit, and the second integrated circuit may include a logic circuit. The first semiconductor chip 210 and the second semiconductor chip 220 may be chiplets that constitute a logic circuit in a semiconductor package. In some examples, the first semiconductor chip 210 and the second semiconductor chip 220 may be chiplets in a semiconductor package for a semiconductor device such as a central processing unit (CPU) device, graphic processing unit (GPU) device, display serial interface (DSI) device, camera serial interface (CSI) device, modulator and demodulator (MODEM) device, or a power management integrated circuit (PMIC) device. In some examples, the second semiconductor chip 220 may include a logic chip including a memory element, a logic semiconductor chip including various integrated elements, or a passive device chip. A bottom surface of the second semiconductor chip 220 may be an active surface, and a top surface of the second semiconductor chip 220 may be an inactive surface. For example, the second semiconductor chip 220 may be disposed face-down on the first redistribution substrate 100.

The second chip wiring layer 224 may be disposed on the bottom surface of the second chip base layer 222. For example, the second chip wiring layer 224 may include a second chip dielectric pattern and a second chip wiring pattern that are formed on the bottom surface of the second chip base layer 222.

On the bottom surface of the second chip base layer 222, the second chip dielectric pattern may cover the second integrated circuit. The second chip dielectric pattern may include a dielectric material. For example, the second chip dielectric pattern may include silicon oxide (SiO), silicon nitride (SiN), silicon oxynitride (SiON), silicon carbonitride (SiCN), or a dielectric polymer. Alternatively, the second chip dielectric pattern may include a dielectric polymer or a photo-imageable dielectric (PID). For example, the photo-imageable dielectric may include at least one selected from photosensitive polyimide, polybenzoxazole, phenolic polymers, and benzocyclobutene polymers.

The second chip wiring pattern may be provided in the second chip dielectric pattern. The second chip wiring pattern may be electrically connected to the second integrated circuit on the bottom surface of the second chip base layer 222. The second chip wiring pattern may include a conductive material. For example, the second chip wiring pattern may include copper (Cu) or aluminum (Al).

The second semiconductor chip 220 may include second chip pads 226 provided on the bottom surface of the second semiconductor chip 220. The second chip pads 226 may be disposed on the bottom surface of the second chip wiring layer 224. The second chip pads 226 may be electrically connected through the second chip wiring pattern in the second chip wiring layer 224 to the second integrated circuit on the bottom surface of the second chip base layer 222.

In some examples, the second chip wiring layer 224 may further include a circuit pattern or a protection layer.

The second semiconductor chip 220 may be mounted on the top surface of the first redistribution substrate 100. For example, the second semiconductor chip 220 may be flip-chip mounted on the top surface of the first redistribution substrate 100. In this configuration, the second semiconductor chip 220 may be electrically connected through second connection terminals 228 to a set of the first substrate pads 122 of the first redistribution substrate 100. The second connection terminals 228 may be provided between the second chip pads 226 of the second semiconductor chip 220 and the set of the first substrate pads 122 of the first redistribution substrate 100.

The bridge chip 500 may be disposed on a bottom surface of the first redistribution substrate 100. The bridge chip 500 may be disposed on the bottom surface of the first redistribution substrate 100 in the first region R1 of the semiconductor package. The bridge chip 500 may have a front surface and a rear surface. In the following description, the term “front surface” may be defined to indicate an active surface of an integrated element in a semiconductor chip, a surface on which wiring lines are formed, or a surface on which pads of a semiconductor chip are formed, and the term “rear surface” may be defined to indicate a surface opposite to the front surface. The front surface of the bridge chip 500 may be directed toward the first redistribution substrate 100. For example, the bridge chip 500 may be disposed face-down on the bottom surface of the first redistribution substrate 100. The bridge chip 500 may be positioned between some external terminals 150 and other external terminals 150 on the bottom of the first redistribution substrate 100. The bridge chip 500 may have a thickness less than that of the external terminals 150. A vertical distance from the bottom surface of the first redistribution substrate 100 to a bottom surface of the bridge chip 500 may be less than a vertical distance from the bottom surface of the first redistribution substrate 100 to a lowermost end of the external terminals 150.

When viewed in plan view, the bridge chip 500 may be disposed adjacent to the first semiconductor chip 210 and the second semiconductor chip 220. For example, as shown in FIG. 1, the bridge chip 500 may overlap not only a portion of the first semiconductor chip 210, but a portion of the second semiconductor chip 220 as well. The present inventive concepts, however, are not limited thereto. When viewed in plan view, the bridge chip 500 may be positioned between the first semiconductor chip 210 and the second semiconductor chip 220, or may overlap only one of the first semiconductor chip 210 and the second semiconductor chip 220.

The bridge chip 500 may include a bridge base layer 502 and a bridge wiring layer 504. The bridge base layer 502 may include or may be a semiconductor substrate, such as a semiconductor wafer. The bridge base layer 502 may be a silicon (Si) substrate, a silicon-on-insulator (SOI) substrate, a germanium (Ge) substrate, a germanium-on-insulator (GOI) substrate, a silicon-germanium (SiGe) substrate, a III-V group semiconductor substrate, or an epitaxial film substrate obtained by performing selective epitaxial growth (SEG). The bridge base layer 502 may include, for example, at least one selected from silicon (Si), germanium (Ge), silicon germanium (SiGe), gallium arsenic (GaAs), indium gallium arsenic (InGaAs), aluminum gallium arsenic (AlGaAs), and a mixture thereof.

The bridge wiring layer 504 may be disposed on a top surface of the bridge base layer 502. For example, the bridge wiring layer 504 may include a bridge dielectric pattern and a bridge wiring pattern that are formed on the top surface of the bridge base layer 502. In some examples, the bridge wiring layer 504 may further include a circuit pattern or a protection layer.

The bridge dielectric pattern may include a dielectric material. For example, the bridge dielectric pattern may include silicon oxide (SiO), silicon nitride (SiN), silicon oxynitride (SiON), silicon carbonitride (SiCN), or a dielectric polymer. Alternatively, the bridge dielectric pattern may include a dielectric polymer or a photo-imageable dielectric (PID).

The bridge wiring pattern may be provided in the bridge dielectric pattern. The bridge wiring pattern may include structure for providing an electrical connection between the first semiconductor chip 210 and the second semiconductor chip 220. The bridge wiring pattern may include a conductive material. For example, the bridge wiring pattern may include copper (Cu) or aluminum (Al).

A portion of the bridge wiring pattern may be exposed on a top surface of the bridge wiring layer 504. The portion of the bridge wiring pattern exposed on the top surface of the bridge wiring layer 504 may be bridge chip pads 506 of the bridge chip 500. Some bridge chip pads 506 may be electrically connected through the bridge wiring pattern in the bridge wiring layer 504 to other bridge chip pads 506.

FIG. 1 depicts that the bridge dielectric pattern is a single layer, but the present inventive concepts are not limited thereto. According to some embodiments, the bridge dielectric pattern may have a plurality of dielectric layers, and the bridge wiring pattern may be a wiring pattern provided in the plurality of dielectric layers.

The bridge chip 500 may be mounted on the bottom surface of the first redistribution substrate 100. For example, the bridge chip 500 may be flip-chip mounted on the bottom surface of the first redistribution substrate 100. The bridge chip 500 may be electrically connected through bridge connection terminals 508 to a set of the external pads 130 of the first redistribution substrate 100. The bridge connection terminals 508 may be provided between the bridge chip pads 506 of the bridge chip 500 and the set of the external pads 130 of the first redistribution substrate 100.

The first semiconductor chip 210 and the second semiconductor chip 220 may be electrically connected to each other through the first redistribution substrate 100 and the bridge chip 500.

According to some embodiments of the present inventive concepts, the first redistribution substrate 100 may not include a horizontal wiring line for connecting the first semiconductor chip 210 to the second semiconductor chip 220. For example, the first redistribution substrate 100 may include wiring lines for connecting the first semiconductor chip 210 to the bridge chip 500 and for connecting the second semiconductor chip 220 to the bridge chip 500, but may not include a horizontal wiring line for connecting the first semiconductor chip 210 to the second semiconductor chip 220. Therefore, there may be a reduction in the number of wiring lines used for the first redistribution substrate 100, and the first redistribution substrate 100 may be provided with a smaller number of first substrate wiring layers. This may enable reductions in the thickness of the first redistribution substrate 100 and the size of the semiconductor package that includes the first redistribution substrate 100.

The bridge chip 500 may provide a horizontal wiring line for connection between the first semiconductor chip 210 and the second semiconductor chip 220. The bridge wiring pattern in the bridge wiring layer 504 of the bridge chip 500 may be a wiring pattern manufactured in a chip scale, and may have a scale (e.g., line-width, height, and thickness) less than that of the first substrate wiring pattern 120 of the first redistribution substrate 100. For example, the bridge wiring layer 504 of the bridge chip 500 may have higher wiring integration than that of the first redistribution substrate 100. Accordingly, electrical connectivity between the first semiconductor chip 210 and the second semiconductor chip 220 may be provided using a semiconductor package of smaller size and improved electrical properties.

Referring still to FIG. 1, the passive device chip 600 may be disposed on a bottom surface of the first redistribution substrate 100. The passive device chip 600 may be disposed on the bottom surface of the first redistribution substrate 100 in the first region R1 of the semiconductor package or in the second region R2 of the semiconductor package. The passive device chip 600 may be disposed horizontally spaced apart from the bridge chip 500. The passive device chip 600 may be positioned between some external terminals 150 and other external terminals 150 on the bottom of the first redistribution substrate 100. The passive device chip 600 may have a thickness less than that of the external terminals 150. A vertical distance from the bottom surface of the first redistribution substrate 100 to a bottom surface of the passive device chip 600 may be less than a vertical distance from the bottom surface of the first redistribution substrate 100 to a bottom end of the external terminals 150.

The passive device chip 600 may include a passive device therein. For example, the passive device may include a resistor, a capacitor, or an inductor. The passive device may be a capacitor that includes a first electrode and a second electrode that are spaced apart from each other and also includes a dielectric that fills a space between the first electrode and the second electrode. The first electrode and the second electrode may be connected to passive device pads 606 of the passive device chip 600. The passive device pads 606 may be a wiring line or pad formed on a front surface of the passive device chip 600.

The passive device chip 600 may be mounted on the bottom surface of the first redistribution substrate 100. For example, the passive device chip 600 may be flip-chip mounted on the bottom surface of the first redistribution substrate 100. The passive device chip 600 may be electrically connected through passive device connection terminals 608 to a set of the external pads 130 of the first redistribution substrate 100. The passive device connection terminals 608 may be provided between the passive device pads 606 of the passive device chip 600 and the set of the external pads 130 of the first redistribution substrate 100.

The conductive posts 300 may be disposed on the top surface of the first redistribution substrate 100. The conductive posts 300 may be disposed on the top surface of the first redistribution substrate 100 in the second region R2 of the semiconductor package. The conductive posts 300 may be disposed horizontally spaced apart from the first semiconductor chip 210 and the second semiconductor chip 220. The conductive posts 300 may be disposed on the second substrate pads 124 of the first redistribution substrate 100. For example, each of the conductive posts 300 may be in contact with a top surface of one of the second substrate pads 124 included in the first redistribution substrate 100. The conductive posts 300 may be a vertical electrical connection structure for connecting the first redistribution substrate 100 to the second redistribution substrate 400 which will be discussed below. For example, the conductive posts 300 may correspond to vertical electrical connection terminals. The conductive posts 300 may each have a pillar shape that extends in a vertical direction with respect to a top surface of the first redistribution substrate 100. The present inventive concepts, however, are not limited thereto, and the conductive posts 300 may be provided with various shapes for vertical connection. In some examples, the conductive posts 300 may each have a width that is constant in the vertical direction. For example, each of the conductive posts 300 may have a pillar shape whose width is constant. In other examples, the conductive posts 300 may each have a width that is not constant in the vertical direction, such as a width that decreases with decreasing distance from the first redistribution substrate 100. The conductive posts 300 may include a conductive material. The conductive posts 300 may include a metallic material, such as copper (Cu) or tungsten (W).

Although not shown, each of the conductive posts 300 may further include a seed layer that surrounds a lateral surface of the conductive post 300. The seed layer may conformally cover bottom and lateral surfaces of the conductive post 300. The seed layer may include metal, such as gold (Au).

The molding layer 350 may be provided on top surface of the first redistribution substrate 100. On the first redistribution substrate 100, the molding layer 350 may surround the first semiconductor chip 210, the second semiconductor chip 220, and the conductive posts 300. The molding layer 350 may cover the first semiconductor chip 210 and the second semiconductor chip 220. The conductive posts 300 may vertically penetrate the molding layer 350, and may be exposed through a top surface of the molding layer 350. The molding layer 350 and the conductive posts 300 may have top surfaces that are substantially flat and coplanar with each other. The molding layer 350 may include a molding member. The molding member may include a dielectric polymer material, such as an epoxy molding compound (EMC) or an Ajinomoto build-up film (ABF).

The second redistribution substrate 400 may be provided on the top surface of the molding layer 350. The second redistribution substrate 400 may be in contact with the top surfaces of the conductive posts 300 and the top surface of the molding layer 350.

The second redistribution substrate 400 may include one or more second substrate wiring layers that are stacked on each other. Each of the second substrate wiring layers may include a second substrate dielectric pattern 410 and a second substrate wiring pattern 420 in the second substrate dielectric pattern 410. The second substrate wiring pattern 420 of one second substrate wiring layer may be electrically connected to the second substrate wiring pattern 420 of an adjacent other second substrate wiring layer.

Any particular second substrate dielectric pattern 410 may include a dielectric polymer or a photo-imageable dielectric (PID). For example, the photo-imageable dielectric may include at least one selected from photosensitive polyimide, polybenzoxazole, phenolic polymers, and benzocyclobutene polymers.

Any particular second substrate wiring pattern 420 may be provided on a second substrate dielectric pattern 410. The second substrate wiring pattern 420 may horizontally extend on the second substrate dielectric pattern 410. The second substrate wiring pattern 420 may be provided on a top surface of the second substrate dielectric pattern 410. The second substrate wiring pattern 420 may protrude onto the top surface of the second substrate dielectric pattern 410. On the second substrate dielectric pattern 410, the second substrate wiring pattern 420 may be covered with another second substrate dielectric pattern 410 that overlies the second substrate wiring pattern 420. The second substrate wiring pattern 420 provided on an uppermost second substrate wiring layer may serve as a substrate pad to which is coupled an upper package which will be discussed below. As discussed above, the second substrate wiring pattern 420 may be a pad or line part of the second substrate wiring layer. For example, the second substrate wiring pattern 420 may be a component for horizontal redistribution in the second redistribution substrate 400. The second substrate wiring pattern 420 may include a conductive material. For example, the second substrate wiring pattern 420 may include metal, such as copper (Cu).

The second substrate wiring pattern 420 may have a damascene structure. For example, the second substrate wiring pattern 420 may have a via that protrudes from a bottom surface thereof. The via may be a component for vertically connecting the second substrate wiring patterns 420 of neighboring second substrate wiring layers. For example, the via may extend from the bottom surface of the second substrate wiring pattern 420 to penetrate the second substrate dielectric pattern 410, thereby being coupled to a top surface of the second substrate wiring pattern 420 of an underlying second substrate wiring layer. Alternatively, the via may be component for connecting the conductive post 300 to the second substrate wiring pattern 420 of a lowermost second substrate wiring layer. For example, the via may extend from the bottom surface of the second substrate wiring pattern 420 to penetrate a lowermost second substrate dielectric pattern 410, thereby being coupled to the top surface of the conductive post 300. In this configuration, an upper portion of the second substrate wiring pattern 420 positioned on the second substrate dielectric pattern 410 may be a head part used as a horizontal line or pad, and the via of the second substrate wiring pattern 420 may be a tail part. The tail part may have a width less than that of the head part. The width of the tail part may decrease with increasing distance from the head part of the second substrate wiring pattern 420. For example, the tail part may have a tapered shape. The second substrate wiring pattern 420 may have a T shape.

An upper package 700 may be provided on the lower package. For example, the semiconductor package illustrated in FIG. 1 may be a package-on-package (POP) in which the upper package 700 is mounted on the lower package. The upper package may be mounted on a top surface of the second redistribution substrate 400. The upper package 700 may be positioned on the top surface of the second redistribution substrate 400 in the second region R2. When viewed in plan view, the upper package 700 may be spaced apart from the first region R1. When viewed in plan view, the upper package 700 may be spaced apart from the first semiconductor chip 210 and the second semiconductor chip 220. For example, the upper package 700 may not cover any of the first semiconductor chip 210 and may not cover any of the second semiconductor chip 220. FIG. 1 depicts and explains that the upper package 700 is horizontally spaced apart from the first region R1, but the present inventive concepts are not limited thereto. As illustrated in FIG. 2, a portion of the upper package 700 may extend into the first region R1. In this case, the upper package 700 may be disposed horizontally spaced apart from the second semiconductor chip 220, may cover a portion of the first semiconductor chip 210, and may not cover a remaining portion of the first semiconductor chip 210, such that it does not entirely cover the first semiconductor chip 210. The following description will focus on the embodiment of FIG. 1.

The upper package 700 may include an upper package substrate 710, an upper package chip 720, and an upper molding layer 730. The upper package substrate 710 may be a printed circuit board (PCB). Alternatively, the upper package substrate 710 may be a redistribution substrate. The upper package substrate 710 may be provided with upper substrate pads 712 on a bottom surface thereof.

The upper package chip 720 may be disposed on a top surface of the upper package substrate 710. The upper package chip 720 may include integrated circuits, and the integrated circuits may include a memory circuit, a logic circuit, or a combination thereof. The upper package chip 720 may be a semiconductor chip whose type is different from that of the first and second semiconductor chips 210 and 220. For example, the upper package chip 720 may be a memory chip. The upper package chip 720 may be electrically connected to the upper package substrate 710 through upper connection terminals 722. FIG. 1 depicts the upper package chip 720 as being flip-chip mounted, but the upper package chip 720 may be mounted in a wire bonding manner or any other suitable manner.

The upper molding layer 730 may be provided on the top surface of the upper package substrate 710. On the upper package substrate 710, the upper molding layer 730 may surround the upper package chip 720. The upper molding layer 730 may cover the top surface of the upper package chip 720. The upper molding layer 730 may include a dielectric polymer, such as an epoxy-based polymer.

Intermediate connection terminals 714 may be disposed between the lower package and the upper package 700. The intermediate connection terminals 714 may be interposed between an uppermost second substrate wiring pattern 420 of the second redistribution substrate 400 and the upper substrate pads 712 of the upper package substrate 710, thereby electrically connecting the second substrate wiring pattern 420 to the upper substrate pads 712. Therefore, the upper package 700 may be electrically connected to the first and second semiconductor chips 210 and 220 and the external terminals 150 through the intermediate connection terminals 714, the second redistribution substrate 400, the conductive posts 300, and the first redistribution substrate 100.

A thermal radiation member 800 may be provided on the lower package. The thermal radiation member may be a heat radiator. The thermal radiation member 800 may be disposed on the top surface of the second redistribution substrate 400. The thermal radiation member 800 may be disposed horizontally spaced apart from the upper package 700. The thermal radiation member 800 may be positioned on the top surface of the second redistribution substrate in the first region R1. The thermal radiation member 800 may be disposed above the first semiconductor chip 210 and the second semiconductor chip 220. The thermal radiation member 800 may be disposed as being connected to the top surface of the second redistribution substrate 400. For example, the thermal radiation member 800 may be attached through an adhesive film 802 to the second redistribution substrate 400. The adhesive film 802 may include a thermal interface material (TIM) such as thermal grease. The thermal radiation member 800 may outwardly radiate heat generated from the first semiconductor chip 210 and the second semiconductor chip 220. The thermal radiation member 800 may include a heat sink. The thermal radiation member 800 may include a thermally-conductive material such as a metal. For example, the thermal radiation member 800 may include copper (Cu) or aluminum (Al).

According to some embodiments of the present inventive concepts, another semiconductor chip or package (e.g., the upper package 700) may not be provided above the first semiconductor chip 210 and the second semiconductor chip 220. Therefore, heat generated from the first and second semiconductor chips 210 and 220 in the lower package may not be blocked (from dissipating) by another semiconductor chip or package, and heat generated by another semiconductor chip or package may not be transmitted to the first and second semiconductor chips 210 and 220. Due to the presence of the thermal radiation member 800 attached to the top surface of the second redistribution substrate 400 above the first and second semiconductor chips 210 and 220, it may be possible to effectively discharge heat generated from the first and second semiconductor chips 210 and 220. Accordingly, the semiconductor package may benefit from increased thermal radiation efficiency and improved electrical properties.

In the embodiments that follow, elements the same as those discussed in the embodiments of FIGS. 1 and 2 are allocated with the same reference numerals, and a repetitive explanation thereof will be omitted or abridged for convenience of description. The following will focus on differences between the embodiments of FIGS. 1 and 2 and other embodiments described below.

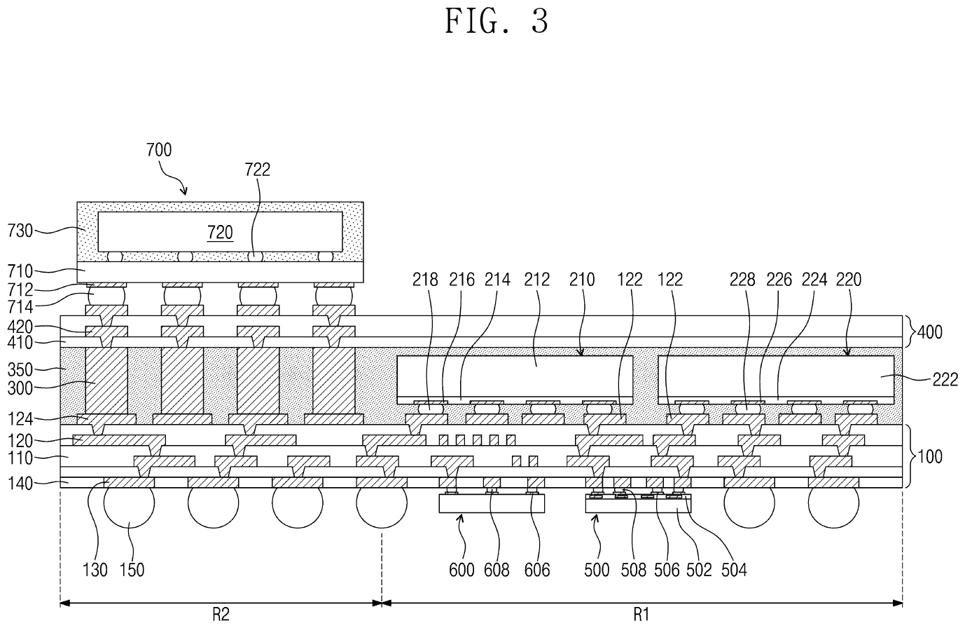

FIG. 3 illustrates a cross-sectional view showing a semiconductor package according to some embodiments of the present inventive concepts.

Referring to FIG. 3, the lower package includes the first redistribution substrate 100, the first and second semiconductor chips 210 and 220, the conductive posts 300, the molding layer 350, the second redistribution substrate 400, the bridge chip 500, and the passive device chip 600.

The upper package 700 may be provided on the lower package. The upper package 700 may be positioned on the top surface of the second redistribution substrate 400 in the second region R2. When viewed in plan view, the upper package 700 may be spaced apart from the first region R1. For example, the upper package 700 may not cover any of the first semiconductor chip 210 and may not cover any of the second semiconductor chip 220.

The semiconductor package may have no thermal radiation member. In the first region R1, the top surface of the second redistribution substrate 400 may be exposed.

According to some embodiments of the present inventive concepts, another semiconductor chip or package (e.g., the upper package 700) may not be provided in the first region R1 on the top surface of the second redistribution substrate 400 above the first semiconductor chip 210 and the second semiconductor chip 220. Therefore, heat generated from the first and second semiconductor chips 210 and 220 in the lower package may not be blocked (from dissipating) by another semiconductor chip or package, and heat generated by another semiconductor chip or package may not be transmitted to the first and second semiconductor chips 210 and 220. Accordingly, even without the inclusion of the thermal radiation member 800 of FIG. 1, the semiconductor package may benefit from increased thermal radiation efficiency and improved electrical properties.

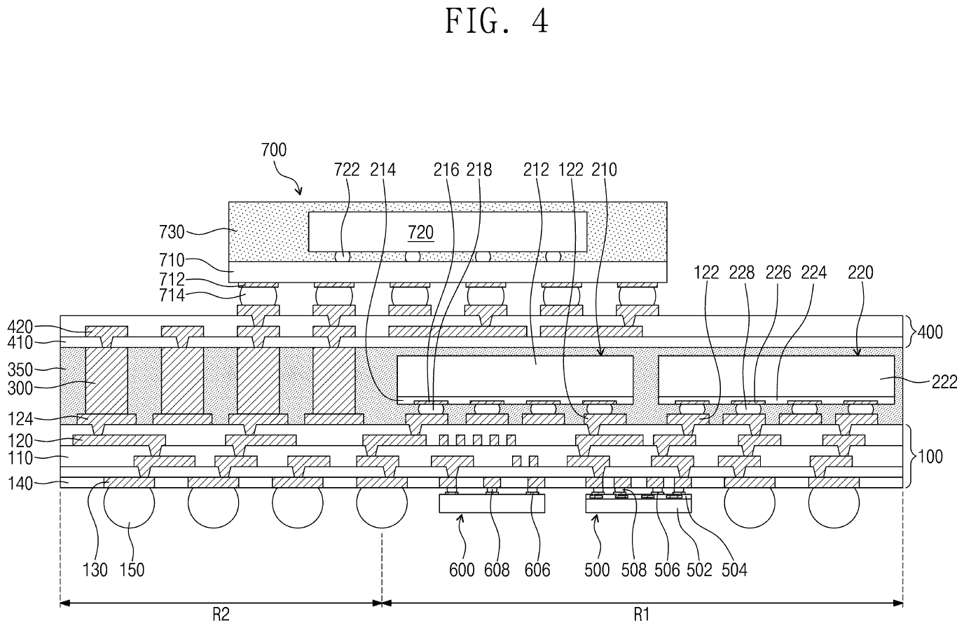

FIG. 4 illustrates a cross-sectional view showing a semiconductor package according to some embodiments of the present inventive concepts.

In contrast to FIG. 3, which depicts and explains that the upper package 700 is horizontally spaced apart from the first region R1, FIG. 4 depicts a portion of the upper package 700 as extending into the first region R1. In this case, the upper package 700 may be disposed horizontally spaced apart from the second semiconductor chip 220. In some examples, the upper package 700 may cover the first semiconductor chip 210 and may not cover the second semiconductor chip 220. In some such examples, the first semiconductor chip 210 may be a chiplet that generates a relatively small amount of heat, and the second semiconductor chip 220 may be a chiplet that generates a larger amount of heat.

According to some embodiments of the present inventive concepts, the semiconductor package may be provided with an upper package 700 having a large size, such that it covers at least a portion of the chiplets in the lower package that collectively constitute a logic circuit. The second semiconductor chip 220, which may generate a larger amount of heat, may be positioned in an outer section of the lower package, such that the upper package 700 does not cover the second semiconductor chip 220. Therefore, it may be possible to prevent the upper package 700 from blocking heat generated from the second semiconductor chip 220 and to effectively discharge heat generated from the second semiconductor chip 220. Accordingly, the semiconductor package may benefit from increased thermal radiation efficiency and improved electrical properties.

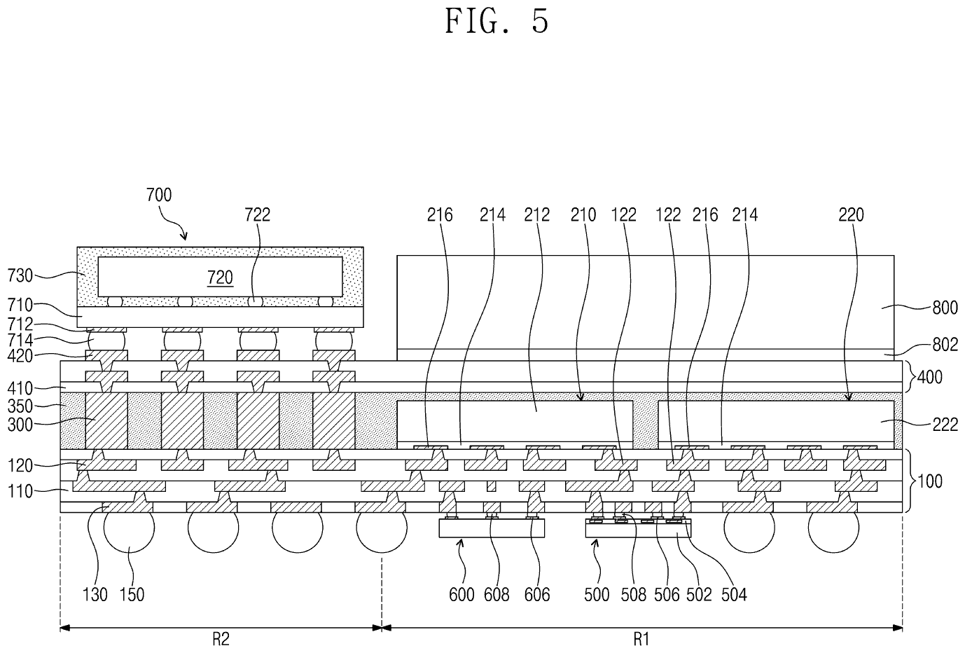

FIG. 5 illustrates a cross-sectional view showing a semiconductor package according to some embodiments of the present inventive concepts.

In contrast to FIG. 1, which depicts that the first and second semiconductor chips 210 and 220 are mounted through the first and second connection terminals 218 and 228 to the first redistribution substrate 100, FIG. 5 depicts the first chip pads 216 of the first semiconductor chip 210 and the second chip pads 226 of the second semiconductor chip 220 as being directly connected to the first substrate wiring pattern 120 of the first redistribution substrate 100.

As in FIG. 1, the lower package includes the first redistribution substrate 100, the first and second semiconductor chips 210 and 220, the molding layer 350 that covers the top surfaces of the first and second semiconductor chips 210 and 220, the conductive posts 300 that vertically penetrate the molding layer 350 on one side of the first and second semiconductor chips 210 and 220, and the second redistribution substrate 400 on the molding layer 350. In this case, the bottom surfaces of the first semiconductor chip 210, the second semiconductor chip 220, and the conductive posts 300 may be exposed on a bottom surface of the molding layer 350. The bottom surfaces of the first semiconductor chip 210, the second semiconductor chip 220, the conductive posts 300, and the molding layer 350 may be substantially flat and coplanar with each other.

The first redistribution substrate 100 may be provided beneath the molding layer 350. The first redistribution substrate 100 may include one or more first substrate wiring layers that are stacked on each other. Each of the first substrate wiring layers may include a first substrate dielectric pattern 110 and a first substrate wiring pattern 120 in the first substrate dielectric pattern 110. The first substrate dielectric pattern 110 may cover the bottom surface of the first semiconductor chip 210, the bottom surface of the second semiconductor chip 220, the bottom surfaces of the conductive posts 300, and the bottom surface of the molding layer 350.

The first substrate wiring pattern 120 may have a damascene structure. For example, the first substrate wiring pattern 120 may have a via that protrudes from a top surface thereof. The via may be a component for vertically connecting the first substrate wiring patterns 120 of neighboring first substrate wiring layers. Alternatively, the via may be a component for connecting the first substrate wiring pattern 120 of an uppermost first substrate wiring layer to a first chip pad 216, a second chip pad 226, or a conductive post 300. For example, the via may extend from a top surface of the first substrate wiring pattern 120 to penetrate the first substrate dielectric pattern 110, thereby being coupled to a bottom surface of the first substrate wiring pattern 120 of an overlying first substrate wiring layer. For another example, the via may extend from a top surface of the first substrate wiring pattern 120 to penetrate an uppermost first substrate dielectric pattern 110, thereby being coupled to a bottom surface of a first chip pad 216, a bottom surface of a second chip pad 226, or a bottom surface of a conductive post 300. The first substrate wiring pattern 120 may have an inverse T shape.

On a lowermost one of the first substrate wiring layers, the first substrate wiring pattern 120 may be exposed on a bottom surface of the first substrate dielectric pattern 110. A lowermost first substrate wiring pattern 120 may serve as external pads 130 of the first redistribution substrate 100.

The bridge chip 500 and the passive device chip 600 may be mounted on a portion of the lowermost first substrate wiring pattern 120, in the first region R1. The external terminals 150 may be coupled to other portions of the first substrate wiring pattern 120.

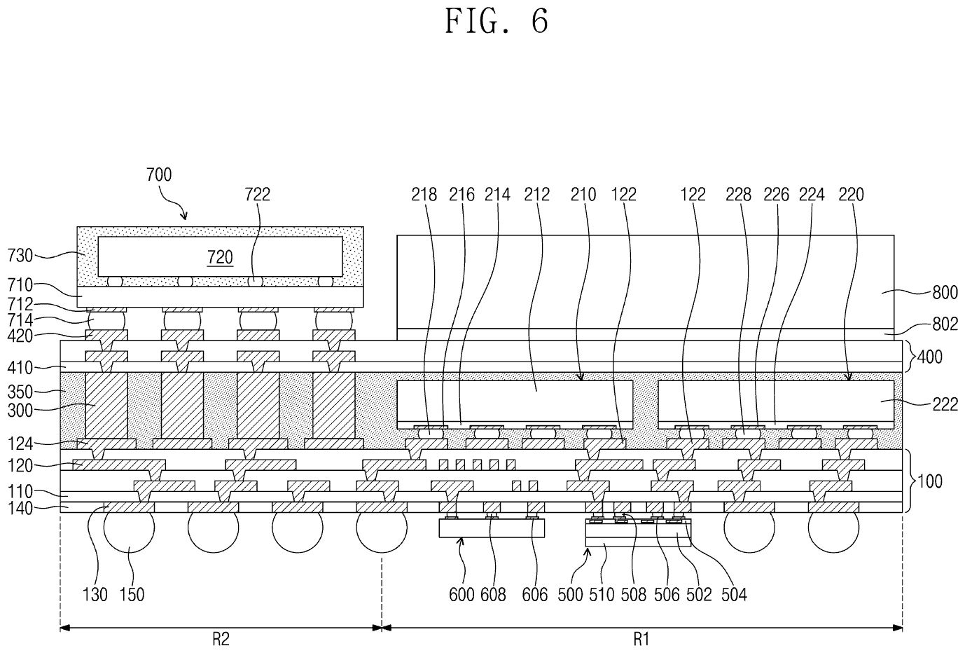

FIG. 6 illustrates a cross-sectional view showing a semiconductor package according to some embodiments of the present inventive concepts.

Referring to FIG. 6, the bridge chip 500 may further include a capacitor element 510. In some examples, as shown in FIG. 6, the capacitor element 510 may be provided or formed on a rear surface of the bridge chip 500. In some other examples, differently from that shown in FIG. 6, the capacitor element 510 may be provided or formed in the bridge base layer 502. Although not shown in detail, the capacitor element 510 may include electrodes that are spaced apart from each other, and may also include a dielectric that fills a space between the electrodes. The electrodes may be connected to the bridge chip pads 506 through the bridge wiring layer 504 of the bridge chip 500.

According to some embodiments of the present inventive concepts, including the capacitor element 510 in the bridge chip 500 may enable a reduction in the size of the passive device chip 600. For instance, including the capacitor element 510 in the bridge chip 500 may enable the use of a smaller capacitor as the passive device chip 600. In some examples, including the capacitor element 510 in the bridge chip 500 may allow the passive device chip 600 to be omitted from the semiconductor package. The reduction in size (or omission) of the passive device chip 600 may enable a corresponding reduction in the amount of surface area of the first redistribution substrate 100 that is occupied by the passive device chip 600. As a result, it may be possible to achieve a more compact semiconductor package.

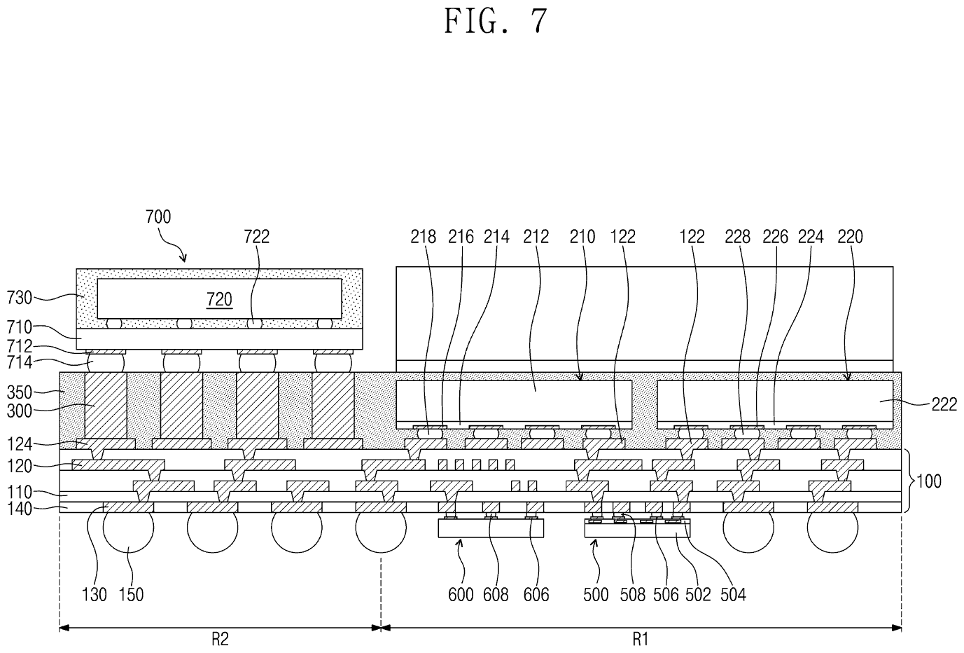

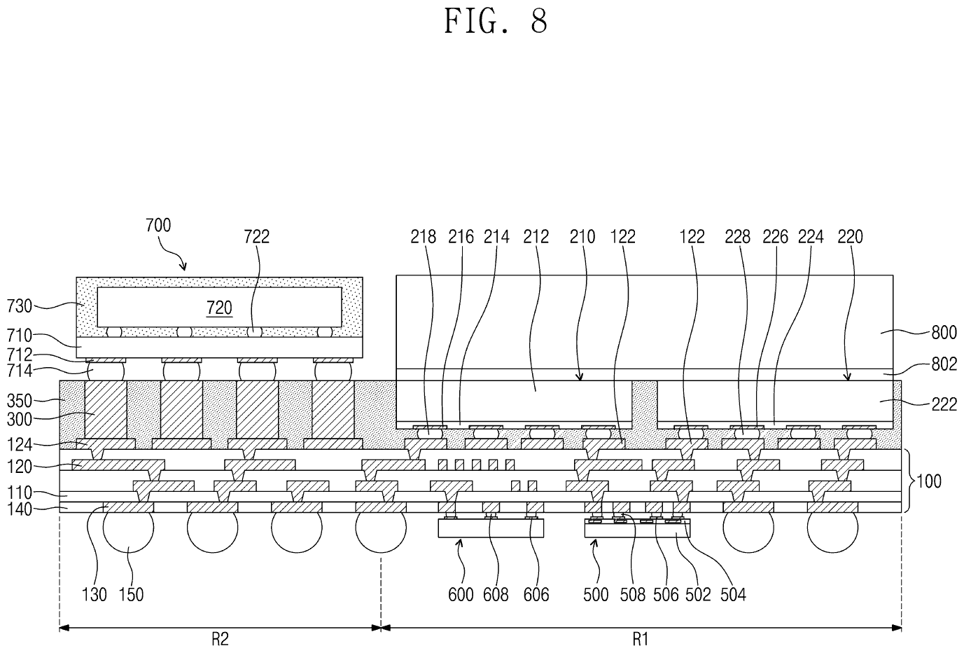

FIGS. 7 and 8 illustrate cross-sectional views showing a semiconductor package according to some embodiments of the present inventive concepts.

FIG. 7 depicts an example in which the lower package does not include the second redistribution substrate 400.

In FIG. 7, the lower package includes the first redistribution substrate 100, the first and second semiconductor chips 210 and 220, the molding layer 350 that covers the top surfaces of the first and second semiconductor chips 210 and 220, and the conductive posts 300 that vertically penetrate the molding layer 350 on one side of the first and second semiconductor chips 210 and 220. The conductive posts 300 may have their top surfaces exposed on a top surface of the molding layer 350. The top surfaces of the conductive posts 300 and the top surface of the molding layer 350 may be substantially flat and coplanar with each other. The present inventive concepts, however, are not limited thereto. For example, in the second region R2, the top surface of the molding layer 350 may have recesses toward the first redistribution substrate 100, and the top surfaces of the conductive posts 300 may extend only as far as the bottoms of the recesses. In this case, the top surfaces of the conductive posts 300 may be located at a lower level than that of the top surface of the molding layer 350.

The upper package 700 may be provided on the lower package. The upper package 700 may be positioned on the top surface of the molding layer 350 in the second region R2. When viewed in plan view, the upper package 700 may be spaced apart from the first region R1. The upper package 700 may not cover any of the first semiconductor chip 210 and may not cover any of the second semiconductor chip 220.

The intermediate connection terminals 714 may be disposed between the lower package and the upper package 700. The intermediate connection terminals 714 may be interposed between the top surfaces of the conductive posts 300 and the bottom surfaces of the upper substrate pads 712 of the upper package substrate 710, thereby electrically connecting the conductive posts 300 to the upper substrate pads 712. Therefore, the upper package 700 may be electrically connected through the intermediate connection terminals 714, the conductive posts 300, and the first redistribution substrate 100 to the first and second semiconductor chips 210 and 220 and the external terminals 150.

The thermal radiation member 800 may be provided on the lower package. The thermal radiation member 800 may be disposed on the top surface of the molding layer 350. The thermal radiation member 800 may be disposed horizontally spaced apart from the upper package 700. The thermal radiation member 800 may be positioned on the top surface of the molding layer 350 in the first region R1. The thermal radiation member 800 may be disposed above the first semiconductor chip 210 and the second semiconductor chip 220. The thermal radiation member 800 may be disposed in contact with the top surface of the molding layer 350. The thermal radiation member 800 may be attached through the adhesive film 802 to the molding layer 350. The thermal radiation member 800 may outwardly radiate heat generated from the first semiconductor chip 210 and the second semiconductor chip 220.

According to some embodiments of the present inventive concepts, as the thermal radiation member 800 is directly attached to the molding layer 350, heat generated from the first and second semiconductor chips 210 and 220 may be easily outwardly discharged through the thermal radiation member 800. Accordingly, the semiconductor package may benefit from increased thermal radiation efficiency and improved electrical properties.

FIG. 7 depicts that the molding layer 350 covers the top surfaces of the first and second semiconductor chips 210 and 220, but the present inventive concepts are not limited thereto.

FIG. 8 depicts an example in which the molding layer 350 does not cover the top surfaces of the first and second semiconductor chips 210 and 220. In FIG. 8, the lower package includes the first redistribution substrate 100, the first and second semiconductor chips 210 and 220, the molding layer 350, and the conductive posts 300 that vertically penetrate the molding layer 350 on one side of the first and second semiconductor chips 210 and 220. The molding layer 350 may surround the first and second semiconductor chips 210 and 220 but not cover the top surfaces of the first and second semiconductor chips 210 and 220. The conductive posts 300, the first semiconductor chip 210, and the second semiconductor chip 220 may have their top surfaces exposed at a top surface of the molding layer 350. The top surfaces of the conductive posts 300, the first semiconductor chip 210, the second semiconductor chip 220, and the molding layer 350 may be substantially flat and coplanar with each other.

The thermal radiation member 800 may be provided on the lower package. The thermal radiation member 800 may be disposed on the top surface of the molding layer 350. The thermal radiation member 800 may be positioned on the top surface of the molding layer 350 in the first region R1. The thermal radiation member 800 may be disposed above the first semiconductor chip 210 and the second semiconductor chip 220. The thermal radiation member 800 may be disposed in contact with the top surface of the molding layer 350. The thermal radiation member 800 may be attached through the adhesive film 802 to the molding layer 350 and the top surfaces of the first and second semiconductor chips 210 and 220 that are exposed at the top surface of the molding layer 350. The thermal radiation member 800 may outwardly radiate heat generated from the first semiconductor chip 210 and the second semiconductor chip 220.

According to some embodiments of the present inventive concepts, as the thermal radiation member 800 is directly attached to the top surfaces of the first and second semiconductor chips 210 and 220, heat generated from the first and second semiconductor chips 210 and 220 may be easily outwardly discharged through the thermal radiation member 800. Accordingly, the semiconductor package may benefit from increased thermal radiation efficiency and improved electrical properties.

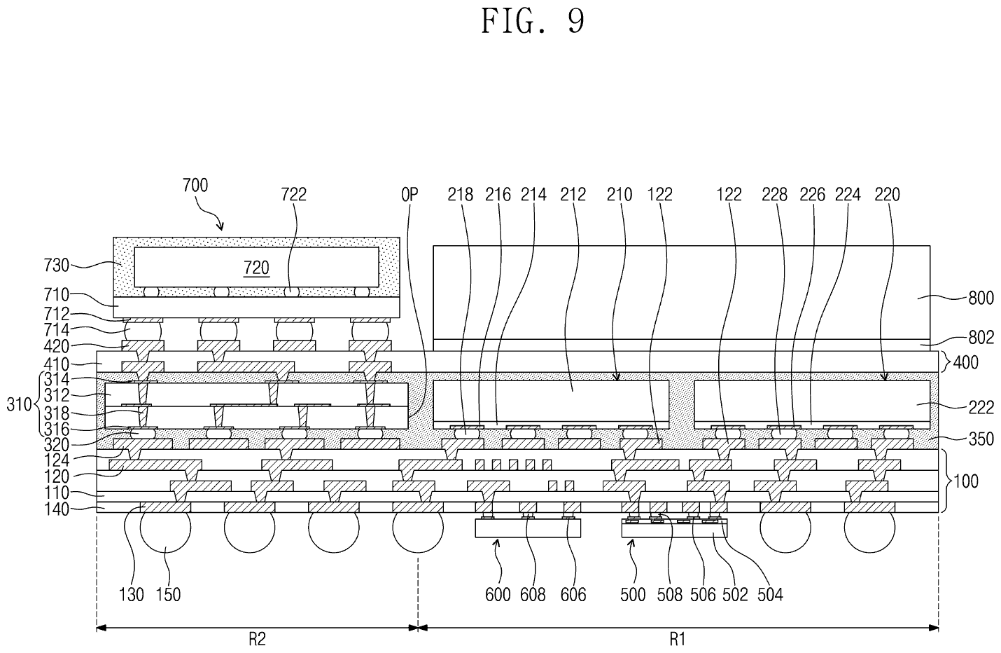

FIG. 9 illustrates a cross-sectional view showing a semiconductor package according to some embodiments of the present inventive concepts.

In FIG. 9, the lower package includes a connection substrate 310 instead of the conductive posts 300.

The connection substrate 310 may be disposed on the top surface of the first redistribution substrate 100. The connection substrate 310 may be disposed on the top surface of the first redistribution substrate in the second region R2. The connection substrate 310 may have a top surface vertically spaced apart from a top surface of the first redistribution substrate 100. The connection substrate 310 may provide a vertical electrical connection structure through which the first redistribution substrate 100 and the second redistribution substrate 400 are connected on one side of the first and second semiconductor chips 210 and 220.

The connection substrate 310 may include a base layer 312 and a conductive member as a wiring pattern provided in the base layer 312. For example, the base layer 312 may include a dielectric material.

The conductive member may include upper pads 314, vias 318, and lower pads 316. The upper pads 314 may be disposed on the top surface of the connection substrate 310. The lower pads 316 may be disposed on a bottom surface of the connection substrate 310. The vias 318 may be through-electrodes that penetrate the base layer 312 and electrically connect the upper pads 314 to the lower pads 316.

The connection substrate 310 may be mounted on the top surface of the first redistribution substrate 100. In some examples, the connection substrate 310 may be electrically connected to the first redistribution substrate 100 through connection substrate terminals 320. The connection substrate terminals 320 may be provided between the lower pads 316 of the connection substrate 310 and a set of the second substrate pads 124 of the first redistribution substrate 100.

On the first redistribution substrate 100, the molding layer 350 may cover the connection substrate 310, the first semiconductor chip 210, and the second semiconductor chip 220. The molding layer 350 may fill a space between the connection substrate 310 and the first and second semiconductor chips 210 and 220. The molding layer 350 may cover the top surface of the connection substrate 310, the top surface of the first semiconductor chip 210, and the top surface of the second semiconductor chip 220. The upper pads 314 of the connection substrate 310 may be electrically connected to the second substrate wiring pattern 420 of the second redistribution substrate 400. For example, the second substrate wiring pattern 420 of the second redistribution substrate 400 may penetrate the second substrate dielectric pattern 410 and the molding layer 350 to electrically couple with the upper pads 314.

FIG. 9 depicts that the first and second semiconductor chips 210 and 220 are mounted through the first and second connection terminals 218 and 228 on the first redistribution substrate 100, and that the connection substrate 310 is mounted through the connection substrate terminals 320 on the first redistribution substrate 100, but the present inventive concepts are not limited thereto.

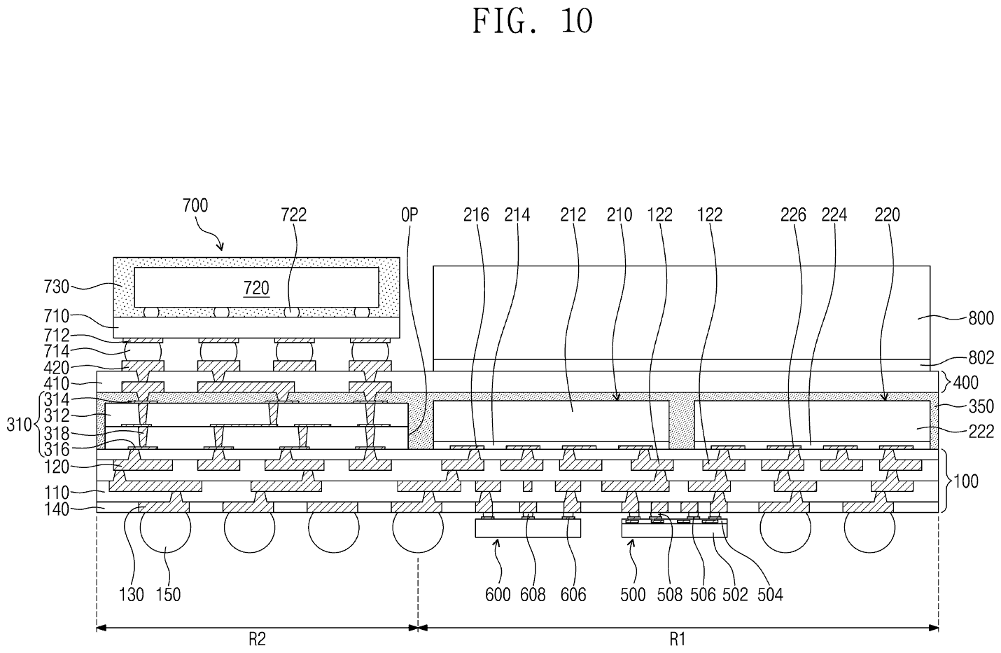

FIG. 10 illustrates a cross-sectional view showing a semiconductor package according to some embodiments of the present inventive concepts. In FIG. 10, the first chip pads 216 of the first semiconductor chip 210, the second chip pads 226 of the second semiconductor chip 220, and the lower pads 316 of the connection substrate 310 may be directly connected to respective portions of the first substrate wiring pattern 120 of the first redistribution substrate 100.

The lower package includes the first redistribution substrate 100, the first and second semiconductor chips 210 and 220, the connection substrate 310 disposed on one side of the first and second semiconductor chips 210 and 220, the molding layer 350 that covers the top surfaces of the first and second semiconductor chips 210 and 220 and the connection substrate 310, and the second redistribution substrate 400 on the molding layer 350. The bottom surfaces of the first semiconductor chip 210, the second semiconductor chip 220, and the connection substrate 310 may be exposed on a bottom surface of the molding layer 350. The bottom surfaces of the first semiconductor chip 210, the second semiconductor chip 220, the connection substrate 310, and the molding layer 350 may be substantially flat and coplanar with each other.

The first redistribution substrate 100 may be provided beneath the molding layer 350. The first redistribution substrate 100 may include one or more first substrate wiring layers that are stacked on each other. Each of the first substrate wiring layers may include a first substrate dielectric pattern 110 and a first substrate wiring pattern 120 in the first substrate dielectric pattern 110. The first substrate dielectric pattern 110 and the first substrate wiring pattern 120 may be substantially the same as or similar to that discussed with reference to FIG. 5. The first substrate dielectric pattern 110 may cover the bottom surface of the first semiconductor chip 210, the bottom surface of the second semiconductor chip 220, the bottom surface of the connection substrate 310, and the bottom surface of the molding layer 350.

The first substrate wiring pattern 120 may have a via that protrudes from a top surface thereof. The via may be a component for vertically connecting the first substrate wiring patterns 120 of neighboring first substrate wiring layers, or for vertically connecting the first substrate wiring pattern 120 of an uppermost first substrate wiring layer to the first chip pads 216, the second chip pads 226, and the lower pads 316 of the connection substrate 310. For example, the via may extend from the top surface of the first substrate wiring pattern 120 to penetrate an uppermost first substrate dielectric pattern 110, thereby being coupled to a bottom surface of a first chip pad 216, a bottom surface of a second chip pad 226, or a bottom surface of a lower pad 316 of the connection substrate 310.

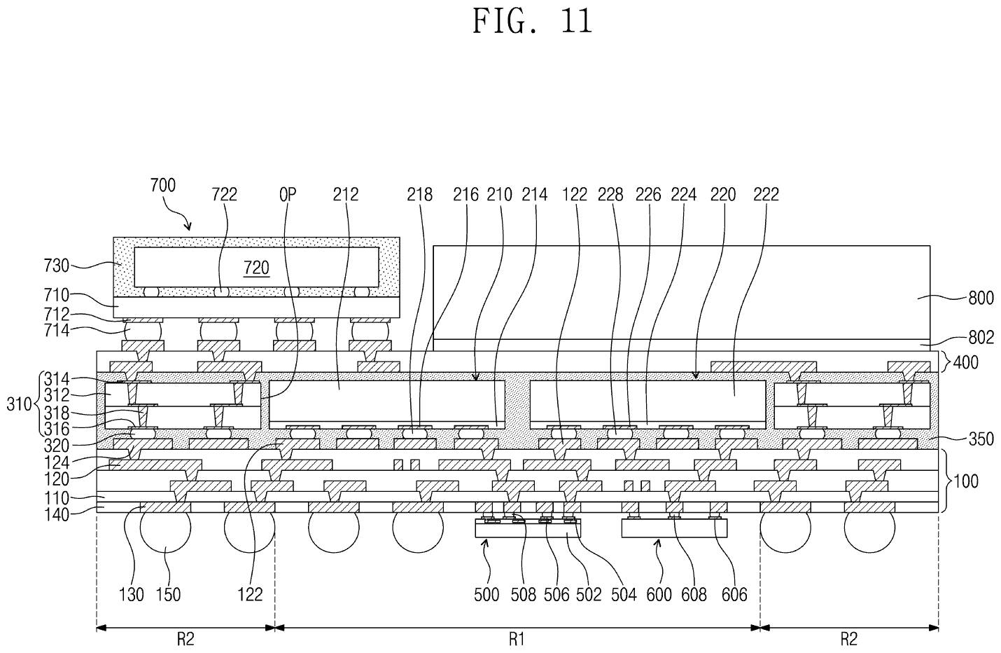

FIG. 11 illustrates a cross-sectional view showing a semiconductor package according to some embodiments of the present inventive concepts.

In FIG. 11, the first region R1 may be a central section of the first redistribution substrate 100, and the second region R2 may include left and right edge sections of the first redistribution substrate 100, such that it horizontally surrounds the first region R1.

The first semiconductor chip 210 and the second semiconductor chip 220 may be provided on the first redistribution substrate 100. The first semiconductor chip 210 and the second semiconductor chip 220 may be disposed on the top surface of the first redistribution substrate 100 in the first region R1.

The connection substrate 310 may also be disposed on the first redistribution substrate 100. The connection substrate 310 may be disposed on the top surface of the first redistribution substrate 100 in the second region R2. The connection substrate 310 may have an opening OP that penetrates therethrough. For example, the opening OP may be shaped like an open hole that connects top and bottom surfaces of the connection substrate 310. The opening OP may be disposed on the top surface of the first redistribution substrate 100 in the first region R1. The connection substrate 310 may provide a vertical electrical connection structure through which the first redistribution substrate 100 and the second redistribution substrate 400 are connected on one side of the first and second semiconductor chips 210 and 220. The connection substrate 310 may include a base layer 312 and a conductive member as a wiring pattern provided in the base layer 312. The conductive member may occupy an outer side of the connection substrate 310, and the opening OP may occupy an inner side of the connection substrate 310. The conductive member may include upper pads 314, vias 318, and lower pads 316.

The first semiconductor chip 210 and the second semiconductor chip 220 may be disposed in the opening OP of the connection substrate 310. When viewed in plan view, the first semiconductor chip 210 and the second semiconductor chip 220 may have a planar shape smaller than that of the opening OP. For example, the first semiconductor chip 210 and the second semiconductor chip 220 may be spaced apart from an inner sidewall of the opening OP.

On the first redistribution substrate 100, the molding layer 350 may cover the connection substrate 310, the first semiconductor chip 210, and the second semiconductor chip 220. The molding layer 350 may fill a space between the connection substrate 310 and the first and second semiconductor chips 210 and 220. For example, the molding layer 350 may fill an unoccupied portion of the opening OP of the connection substrate 310. The molding layer 350 may cover a top surface of the connection substrate 310, a top surface of the first semiconductor chip 210, and a top surface of the second semiconductor chip 220. The upper pads 314 of the connection substrate 310 may be electrically connected to the second substrate wiring pattern 420 of the second redistribution substrate 400. For example, the second substrate wiring pattern 420 of the second redistribution substrate 400 may penetrate the second substrate dielectric pattern 410 and the molding layer 350 to electrically couple with the upper pads 314.

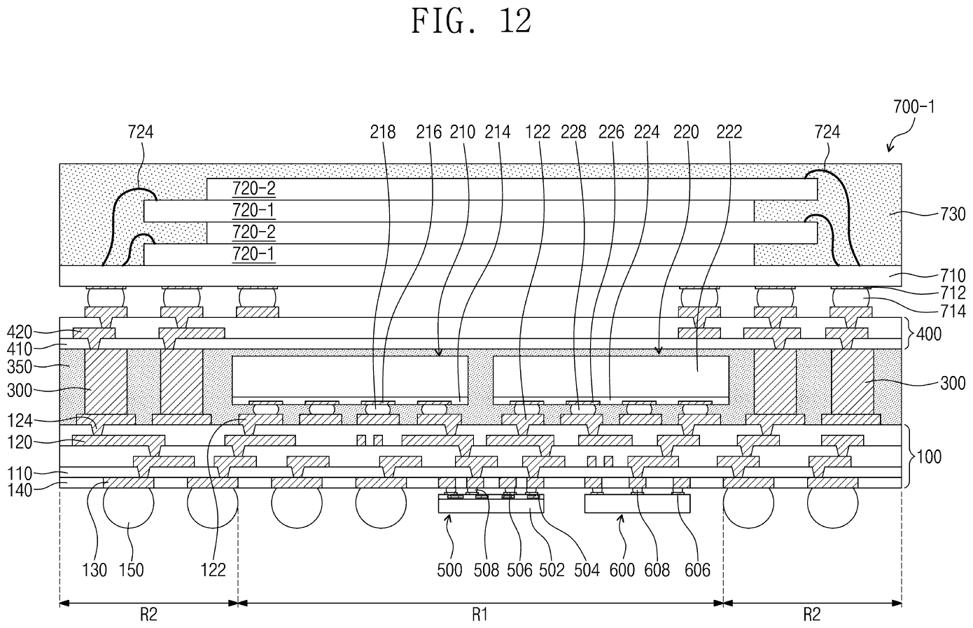

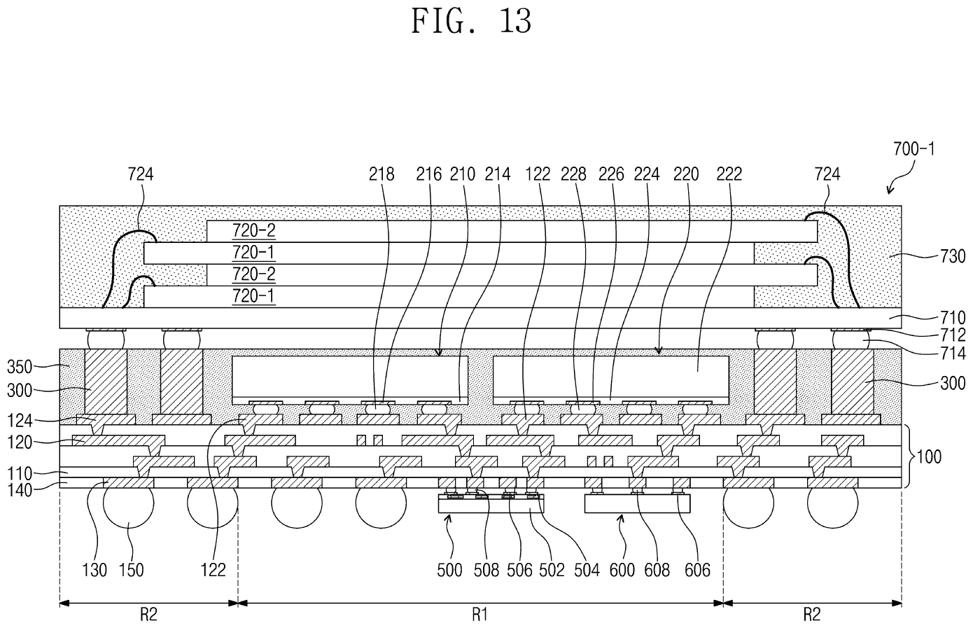

FIGS. 12 and 13 illustrate cross-sectional views showing a semiconductor package according to some embodiments of the present inventive concepts.

In FIG. 12, the lower package includes the first redistribution substrate 100, the first and second semiconductor chips 210 and 220, the conductive posts 300, the molding layer 350, the second redistribution substrate 400, the bridge chip 500, and the passive device chip 600.

As in FIG. 11, the first region R1 may include a central section of the first redistribution substrate 100, and the second region R2 may include left and right edge sections of the first redistribution substrate 100 that horizontally surround the central section of the first redistribution substrate 100.

The first semiconductor chip 210 and the second semiconductor chip 220 may be provided on the first redistribution substrate 100. The first semiconductor chip 210 and the second semiconductor chip 220 may be disposed on the top surface of the first redistribution substrate 100 in the first region R1.

The conductive posts 300 may also be disposed on the first redistribution substrate 100. The conductive posts 300 may be disposed on the top surface of the first redistribution substrate 100 in the second region R2. The conductive posts 300 may be disposed horizontally spaced apart from the first semiconductor chip 210 and the second semiconductor chip 220. The conductive posts 300 may be disposed on the second substrate pads 124 of the first redistribution substrate 100. The conductive posts 300 may each have a pillar shape that extends in a vertical direction with respect to a top surface of the first redistribution substrate 100.

On the first redistribution substrate 100, the molding layer 350 may cover the first semiconductor chip 210 and the second semiconductor chip 220. The conductive posts 300 may be exposed on a top surface of the molding layer 350.

The second redistribution substrate 400 may be provided on the top surface of the molding layer 350. The second redistribution substrate 400 may be in contact with the top surfaces of the conductive posts 300 and the top surface of the molding layer 350. The second redistribution substrate 400 may include one or more second substrate wiring layers that are stacked on each other. Each of the second substrate wiring layers may include a second substrate dielectric pattern 410 and a second substrate wiring pattern 420 in the second substrate dielectric pattern 410. The second substrate wiring pattern 420 provided on an uppermost second substrate wiring layer may serve as a substrate pad to which is coupled an upper package 700-1 which will be discussed below. The second substrate wiring pattern 420 provided on a lowermost second substrate wiring layer may extend from a bottom surface of the second substrate wiring pattern 420 to penetrate the second substrate dielectric pattern 410, thereby being coupled to top surfaces of the conductive posts 300.

An upper package 700-1 may be provided on the lower package. For example, the semiconductor package illustrated in FIG. 12 may be a package-on-package (POP) in which the upper package 700-1 is mounted on the lower package. The upper package 700-1 may be positioned on the top surface of the second redistribution substrate 400, and may overlap, in a plan view, some or all of the first region R1 and some or all the second region R2. FIG. 12 depicts an example in which the upper package 700-1 overlaps all of the first region R1 and all of the second region R2, but the present inventive concepts are not limited thereto. The upper package 700-1 may have a width the same as or similar to that of the lower package. Alternatively, the width of the upper package 700-1 may be less than that of the lower package. The upper package 700-1 may include an upper package substrate 710, first upper package chips 720-1, second upper package chips 720-2, and an upper molding layer 730.

A stack of chips including the first upper package chips 720-1 and the second upper package chips 720-2 may be disposed on an upper surface of the upper package substrate 710. The first upper package chips 720-1 and the second upper package chips 720-2 may be alternately stacked on each other. The first upper package chips 720-1 may be aligned in a direction perpendicular to a top surface of the upper package substrate 710. In some examples, lateral surfaces of the first upper package chips 720-1 may be positioned in a same plane. The second upper package chips 720-2 may also be aligned in the direction perpendicular to the top surface of the upper package substrate 710. In some examples, lateral surfaces of the second upper package chips 720-2 may be positioned in a same plane that is spaced horizontally from a plane in which the lateral surfaces of the first upper package chips 720-1 are positioned. The first upper package chips 720-1 may protrude from adjacent second upper package chips 720-2 in a direction parallel to the top surface of the upper package substrate 710. For example, as shown in FIG. 12, the first upper package chips 720-1 may protrude in a leftward direction from adjacent second upper package chips 720-2. The second upper package chips 720-2 may protrude from adjacent first upper package chips 720-1 in a direction opposite the direction in which the first upper package chips 720-1 protrude. For example, as shown in FIG. 12, the second upper package chips 720-2 may protrude in a rightward direction from adjacent first upper package chips 720-1. The first and second upper package chips 720-1 and 720-2 may be of the same type. The first and second upper package chips 720-1 and 720-2 may include integrated circuits, and the integrated circuits may include a memory circuit, a logic circuit, or a combination thereof. The first and second upper package chips 720-1 and 720-2 may be of different type from the first and second semiconductor chips 210 and 220. For example, the first and second upper package chips 720-1 and 720-2 may be memory chips. The first and second upper package chips 720-1 and 720-2 may be electrically connected to the upper package substrate 710 through bonding wires 724. FIG. 12 illustrates an example of stacking and mounting of the first and second upper package chips 720-1 and 720-2, but the present inventive concepts are not limited thereto.

The upper molding layer 730 may be provided on the top surface of the upper package substrate 710. On the upper package substrate 710, the upper molding layer 730 may surround the first and second upper package chips 720-1 and 720-2. The upper molding layer 730 may cover the top surfaces of the first and second upper package chips 720-1 and 720-2.

The intermediate connection terminals 714 may be disposed between the lower package and the upper package 700-1. The intermediate connection terminals 714 may be interposed between an uppermost second substrate wiring pattern 420 of the second redistribution substrate 400 and the upper substrate pads 712 of the upper package substrate 710, thereby electrically connecting the second substrate wiring pattern 420 to the upper substrate pads 712.

FIG. 13 depicts an example in which the lower package does not include the second redistribution substrate 400.

In FIG. 13, the lower package includes the first redistribution substrate 100, the first and second semiconductor chips 210 and 220, the molding layer 350 that covers the top surfaces of the first and second semiconductor chips 210 and 220, and the conductive posts 300 that vertically penetrate the molding layer 350 on one side of the first and second semiconductor chips 210 and 220. The conductive posts 300 may have their top surfaces exposed on a top surface of the molding layer 350. The top surfaces of the conductive posts 300 and the top surface of the molding layer 350 may be substantially flat and coplanar with each other. The present inventive concepts, however, are not limited thereto. For example, in the second region R2, the top surface of the molding layer 350 may have recesses toward the first redistribution substrate 100, and the top surfaces of the conductive posts 300 may extend only as far as the bottoms of the recesses. In this case, the top surfaces of the conductive posts 300 may be located at a lower level than that of the top surface of the molding layer 350. FIG. 13 depicts that the molding layer 350 covers the top surfaces of the first and second semiconductor chips 210 and 220, but the present inventive concepts are not limited thereto. In some examples, the conductive posts 300, the first semiconductor chip 210, and the second semiconductor chip 220 may each have their top surfaces exposed at the top surface of the molding layer 350. In such examples, the top surfaces of the conductive posts 300, the first semiconductor chip 210, the second semiconductor chip 220, and the molding layer 350 may be substantially flat and coplanar with each other.

In FIG. 13, as in FIG. 12, an upper package 700-1 may be provided on the lower package. The upper package 700-1 may be the same as or similar to that discussed with reference to FIG. 12.

The intermediate connection terminals 714 may be disposed between the lower package and the upper package 700-1. The intermediate connection terminals 714 may be interposed between the top surfaces of the conductive posts 300 and the bottom surfaces of the upper substrate pads 712 of the upper package substrate 710, thereby electrically connecting the conductive posts 300 to the upper substrate pads 712. Therefore, the upper package 700-1 may be electrically connected through the intermediate connection terminals 714, the conductive posts 300, and the first redistribution substrate 100 to the first and second semiconductor chips 210 and 220 and the external terminals 150.

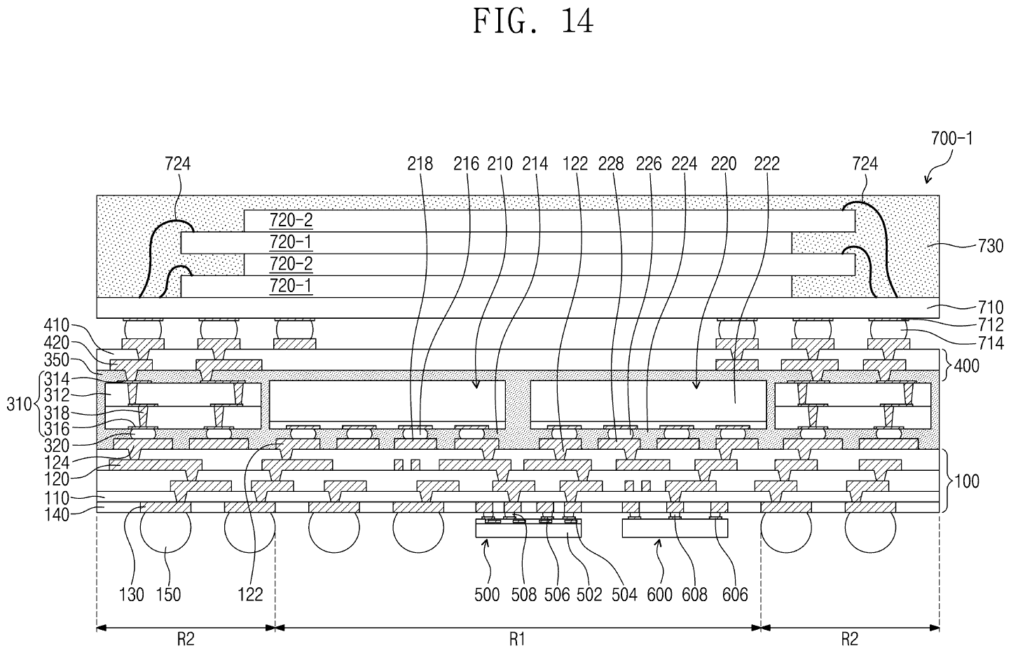

FIG. 14 illustrates a cross-sectional view showing a semiconductor package according to some embodiments of the present inventive concepts.

Referring to FIG. 14, a lower package may be provided that is substantially the same as or similar to the lower package discussed with reference to FIG. 11. For example, the lower package may include the first redistribution substrate 100, the first and second semiconductor chips 210 and 220, the connection substrate 310, the molding layer 350, the second redistribution substrate 400, the bridge chip 500, and the passive device chip 600.

In FIG. 14, as in FIG. 11, the first region R1 may include a central section of the first redistribution substrate 100, and the second region R2 may include left and right edge sections of the first redistribution substrate 100 that horizontally surround the central section of the first redistribution substrate 100.

The first semiconductor chip 210 and the second semiconductor chip 220 may be disposed on the top surface of the first redistribution substrate 100 in the first region R1.

The connection substrate 310 may be disposed on the top surface of the first redistribution substrate 100 in the second region R2.

On the first redistribution substrate 100, the molding layer 350 may cover the connection substrate 310, the first semiconductor chip 210, and the second semiconductor chip 220. The molding layer 350 may fill a space between the connection substrate 310 and the first and second semiconductor chips 210 and 220.

The second redistribution substrate 400 may cover the molding layer 350. The second substrate wiring pattern 420 of the second redistribution substrate 400 may penetrate the second substrate dielectric pattern 410 and the molding layer 350, to electrically couple with the upper pads 314.

An upper package 700-1 may be provided on the lower package. The upper package 700-1 may be substantially the same as or similar to the upper package 700-1 discussed with reference to FIG. 12 or 13. The upper package 700-1 may be positioned on the top surface of the second redistribution substrate 400, and may, in a plan view, overlap some or all of the first region R1 and some or all of the second region R2. The upper package 700-1 may have a width the same as or similar to that of the lower package. Alternatively, the width of the upper package 700-1 may be less than that of the lower package. The upper package 700-1 may include an upper package substrate 710, first and second upper package chips 720-1 and 720-2, and an upper molding layer 730.

FIG. 14 depicts that the lower package includes the second redistribution substrate 400, and that the upper package 700-1 is mounted on the second redistribution substrate 400, but the present inventive concepts are not limited thereto. According to some embodiments, similar to the embodiment of FIG. 13, the lower package may not have the second redistribution substrate 400. In this case, the upper pads 314 of the connection substrate 310 may be exposed on the molding layer 350, and the upper package 700-1 may be directly mounted on the upper pads 314 of the connection substrate 310.

In a semiconductor package according to some embodiments of the present inventive concepts, a first redistribution substrate may include only a wiring line for connecting first and second semiconductor chips to a bridge chip, and the bridge chip may provide a horizontal wiring line for redistributing the first and second semiconductor chips. Therefore, even with respect to the use of the first redistribution substrate for connection of an upper package mounted on a molding layer to the first semiconductor chip or the second semiconductor chip, there may be a reduction in the number of wiring lines required for the first redistribution substrate and the number of substrate wiring layers of the first redistribution substrate. This may enable reductions in the thickness of the first redistribution substrate and the size of the semiconductor package that includes the first redistribution substrate.

In addition, according to some embodiments of the present inventive concepts, another semiconductor chip or package may not be provided above the first and second semiconductor chips, and a thermal radiation member may be provided above the first and second semiconductor chips. Thus, heat generated from the first and second semiconductor chips may be more effectively discharged. Accordingly, the semiconductor package may benefit from increased thermal radiation efficiency and improved electrical properties.

Although the present invention has been described in connection with some embodiments of the present inventive concepts illustrated in the accompanying drawings, it will be understood by one of ordinary skill in the art that variations in form and detail may be made therein without departing from the spirit and essential feature of the present inventive concepts. The above disclosed embodiments should thus be considered illustrative and not restrictive.

1. A semiconductor package, comprising:
a first redistribution substrate;
a first semiconductor chip and a second semiconductor chip that are mounted on a top surface of the first redistribution substrate and horizontally spaced apart from each other;
a molding layer disposed on the top surface of the first redistribution substrate and surrounding the first semiconductor chip and the second semiconductor chip;
a second redistribution substrate disposed on a top surface of the molding layer;
an upper package mounted on a top surface of the second redistribution substrate;
a vertical electrical connection structure disposed on one side of the first and second semiconductor chips and connecting the first redistribution substrate to the second redistribution substrate;
a plurality of external connection terminals disposed on a bottom surface of the first redistribution substrate; and
a bridge chip and a capacitor chip that are mounted on the bottom surface of the first redistribution substrate and are disposed between a first set of the external connection terminals and a second set of the external connection terminals.

2. The semiconductor package of claim 1, wherein
the first semiconductor chip and the second semiconductor chip are mounted on the top surface of the first redistribution substrate in a first region of the semiconductor package,
the vertical electrical connection structure is disposed on the top surface of the first redistribution substrate in a second region of the semiconductor package, and
the second region is horizontally spaced apart from the first region.

3. The semiconductor package of claim 2, further comprising a thermal radiation member attached to a top surface of the second redistribution substrate in the first region,
wherein the upper package is mounted on the top surface of the second redistribution substrate in the second region.

4. The semiconductor package of claim 1, wherein, when viewed in plan view, the upper package is horizontally spaced apart from the second semiconductor chip.

5. The semiconductor package of claim 4, wherein, when viewed in plan view,
the upper package is horizontally spaced apart from the first semiconductor chip, or
the upper package overlaps a portion of the first semiconductor chip and does not overlap another portion of the first semiconductor chip.

6. The semiconductor package of claim 1, wherein a vertical distance from the bottom surface of the first redistribution substrate to a bottom surface of the bridge chip is less than a vertical distance from the bottom surface of the first redistribution substrate to a lowermost end of the external connection terminals.

7. The semiconductor package of claim 1, wherein
at least one of the first semiconductor chip and the second semiconductor chip is a logic chip, and
the upper package includes:
an upper package substrate;
a memory chip mounted on a top surface of the upper package substrate; and
an upper molding layer disposed on the top surface of the upper package substrate and covering a top surface of the memory chip.

8. The semiconductor package of claim 1, wherein
the vertical electrical connection structure includes a connection substrate disposed on the top surface of the first redistribution substrate,
the first semiconductor chip and the second semiconductor chip are horizontally spaced apart from the connection substrate, and
the molding layer fills a space between the connection substrate and the first and second semiconductor chips.

9. The semiconductor package of claim 8, wherein
the connection substrate has an opening that penetrates the connection substrate, and the first and second semiconductor chips are disposed in the opening, and
in the opening, the molding layer fills the space between the connection substrate and the first and second semiconductor chips.

10. The semiconductor package of claim 1, wherein the vertical electrical connection structure includes a conductive post horizontally spaced apart from the first semiconductor chip and the second semiconductor chip, the conductive post vertically penetrating the molding layer and connecting the first redistribution substrate to the second redistribution substrate.

11. The semiconductor package of claim 1, wherein the bridge chip includes a capacitor element therein.

12. The semiconductor package of claim 1, wherein
the upper package is vertically spaced apart from the second redistribution substrate, and
the upper package is mounted on the top surface of the second redistribution substrate through a plurality of intermediate connection terminals between the upper package and the second redistribution substrate.

13. A semiconductor package, comprising:
a lower package; and
an upper package mounted on the lower package,
wherein the lower package includes:
a first redistribution substrate;
a first logic chip and a second logic chip that are mounted on a top surface of the first redistribution substrate in a first region of the semiconductor package;
a molding layer disposed on the top surface of the first redistribution substrate and surrounding the first logic chip and the second logic chip;
a vertical electrical connection structure disposed on the top surface of the first redistribution substrate in a second region of the semiconductor package, the second region horizontally spaced apart from the first region; and
a bridge chip mounted on a bottom surface of the first redistribution substrate,
wherein the upper package includes:
an upper package substrate;
a memory chip mounted on a top surface of the upper package substrate; and
an upper molding layer disposed on the top surface of the upper package substrate and covering a top surface of the memory chip,
wherein the upper package is disposed in the second region of the semiconductor package.

14. The semiconductor package of claim 13, wherein
the lower package further includes a second redistribution substrate disposed on a top surface of the molding layer and electrically connected to the vertical electrical connection structure, and
the upper package is mounted on a top surface of the second redistribution substrate.

15. The semiconductor package of claim 13, wherein
the vertical electrical connection structure is exposed on a top surface of the molding layer, and
the upper package is mounted on the vertical electrical connection structure through a plurality of intermediate connection terminals, the plurality of intermediate connection terminals disposed on a bottom surface of the upper package substrate.

16. The semiconductor package of claim 13, further comprising a plurality of external connection terminals on the bottom surface of the first redistribution substrate,
wherein the bridge chip is disposed between a first set of the external connection terminals and a second set of the external connection terminals.

17. (canceled)

18. The semiconductor package of claim 13, further comprising a thermal radiation member disposed on a top surface of the lower package in the first region.

19. The semiconductor package of claim 13, wherein, when viewed in plan, the upper package is horizontally spaced apart from the first logic chip and the second logic chip.

20. The semiconductor package of claim 13, wherein, when viewed in plan view,
at least a portion of the upper package extends into the first region,
the upper package is horizontally spaced apart from the first logic chip, and
the upper package overlaps a portion of the second logic chip and does not overlap another portion of the second logic chip.

21-23. (canceled)

24. A semiconductor package, comprising:
a first redistribution substrate;
a first semiconductor chip and a second semiconductor chip that are mounted on a top surface of the first redistribution substrate in a first region of the semiconductor package;
a second redistribution substrate disposed above the first semiconductor chip and the second semiconductor chip;
a vertical electrical connection structure disposed on the top surface of the first redistribution substrate in a second region of the semiconductor package and connecting the first redistribution substrate to the second redistribution substrate, the second region horizontally spaced apart from the first region;
an upper package mounted on a top surface of the second redistribution substrate in the second region;
a thermal radiation member attached to the top surface of the second redistribution substrate in the first region;
a plurality of external connection terminals disposed on a bottom surface of the first redistribution substrate; and
a bridge chip that is mounted on the bottom surface of the first redistribution substrate in the first region and is disposed between a first set of the external connection terminals and a second set of the external connection terminals.

25-34. (canceled)
